(19) United States
(12) Patent Application Publication
(10) Pub. No.: US 2002/0061088 A1
(43) Pub. Date: May 23, 2002

(54) Clock signal generator having improved switching characteristics

(76) Inventor: Hirokazu Kon, Yamagata (JP)

Correspondence Address: McGinn & Gibb, PLLC, Suite 200, 8321 Old Courthouse Road, Vienna, VA, 22182-3817, US

(21) Appl. No.: 09/969,999

(22) Filed: Oct. 4, 2001

(30) Foreign Application Priority Data
Oct. 5, 2000 (JP) 2000-305839

(51) Int. Cl. H03D 3/24

(52) U.S. Cl. 375/376; 327/147

(57) ABSTRACT

An optical disk recorder has a clock signal generator which switches between a reproducing clock signal and a recording clock signal. The optical disk recorder records data from the end point of the recorded data after interruption of recording due to buffer under-run phenomenon. In this recording, the optical disk recorder reads out a read clock signal from the recorded data, detects the end point of the recorded data and then starts for recording from the end point based on a recording clock signal, Switching between the reproducing clock signal to the recording clock signal allows a linear change in the output frequency to thereby improve the continuity of the recorded data in the vicinity of the end point.

### BACKGROUND OF THE INVENTION

(a) Field of the Invention

The present invention relates to a clock signal generator having improved switching characteristics and, more particularly, to a clock signal generator for use in a CD-R (compact disk recordable).

(b) Description of the Related Art

Optical disks are widely used in recent years due to a larger storage capacity thereof compared to other record media. Especially, CD-Rs having a compatibility with the current CDs used for dedicated reproduction use are increasingly used for storing music and computer data. An optical disk reader/recorder generally includes a clock signal generator for recording/reproducing data on a CD.

FIG. 1 shows a conventional clock signal generator used in an optical disk reader, described in Patent Publication JP-A-11-120711. The clock signal generator operates for generation of a reproducing clock signal 122 based on the data pulse or read clock signal 121 read from the optical disk.

Both a phase comparator 91 and a frequency comparator 92 compare the read data pulse 121 from the optical disk against the reproducing clock signal 122 to output phase difference signals. The phase comparator 91 is implemented by an exclusive-OR gate or a flip-flop, whereas the frequency comparator 92 includes a frequency divider and a phase comparator.

A mode selector 93 responds to a selection control signal 123, supplied from a selection period setting unit 96, to select one of the outputs from the phase comparator 91 and the frequency comparator 92 and deliver a selected difference signal. A loop filter 94 converts the selected difference signal into a voltage signal, which is delivered to a voltage controlled oscillator (VCO) 95. The VCO 95 generates the reproducing clock signal based on the input voltage signal.

The mode selector 93 selects a phase difference signal delivered from the frequency comparator 92 when the reproducing clock signal 122 has a frequency different from the frequency of the read data pulse 121. This case may occur when the clock signal generator starts for a reproducing operation. In this case, the clock signal generator performs a pull-in operation as a PLL circuit by negating or nullifying the frequency difference between the read data pulse 121 and the reproducing clock signal 122.

If the reproducing cock signal 122 has a frequency equal to the frequency of the read data pulse 121 due to continued reproducing operation, the mode selector 93 selects a phase difference signal delivered from the phase comparator 91. In this case, the clock signal generator performs a pull-in operation as a PLL circuit by negating the phase difference between the read data pulse 121 and the reproducing clock signal 122. Thus, the clock signal generator supplies a reproducing clock signal 122 having a frequency and a phase which are equal to those of the read data pulse 121.

The clock signal generator as described above can be used for generating a recording clock signal by switching the input read data pulse 121 to an external reference clock signal. An optical disk recorder generally uses such a clock signal generator to generate a reproducing clock signal as well as a recording clock signal, as will be described hereinafter.

It is known that a “buffer under-run” phenomenon sometimes occurs during recording data on a CD-R in an optical disk recorder. The buffer under-run phenomenon is such that the data transfer rate is delayed with respect to the data recording rate. Once the buffer under-run phenomenon occurs in the optical disk recorder, the optical disk recorder generally stops or interrupts the recording and awaits until the buffer under-run phenomenon is terminated.

The optical disk recorder, after the buffer under-run phenomenon is terminated, starts for reading the data recorded on the optical disk before the interruption to thereby obtain a reproducing clock signal in synchrony with the read clock signal. The optical disk recorder continues to read recorded data based on the reproducing clock signal, and detects the end of the recorded data and thus the next starting position for recording the data. The optical disk recorder then starts for recording data from the thus detected starting position based on a recording clock signal, which is generated in synchrony with a reference clock signal.

Since the detection of the next starting position is performed with the accuracy determined by the reproducing clock signal, the deviation between the end of the data recorded before the interruption and the start of the data recorded after the interruption can be maintained within a specified allowable range.

An optical disk reader generally includes an error correction circuit for correcting a possible error occurring during reproduction of the data on the optical disk. Thus, the optical disk reader can correctly reproduce the recorded data by using the error correction circuit irrespective of the above deviation so long as the deviation resides within the allowable range.

The clock signal generator used in the optical disk recorder generates the reproducing clock signal based on the recorded data, and also generates the recording clock signal based on the reference clock signal, as described above. Thus, it is required that the clock signal generator switch between the reproducing clock signal and the recording clock signal within a specified time limit.

In the cock signal generator, the pull-in locking operation as a PLL circuit is assured by selecting the phase difference signal.

The recording operation after the interruption caused by the buffer under-run phenomenon in the optical disk recorder is conducted by switching the operational frequency from the reproducing clock signal to the recording clock signal. After the switching operation of the frequency, however, the output frequency from the clock signal generator is in fact unstable. This degrades the continuity of the frequency of the read data pulse in the optical disk reader at the locations of data before and after the interruption, and thus degrades the signal quality of the read data.

### SUMMARY OF THE INVENTION

In view of the above, it is an object of the present invention to provide a clock signal generator for use in an optical disk recorder for recording data on a CD-R, which is capable of switching between the reproducing clock signal and recording clock signal within a fixed time interval, thereby supplying stable clock signal after interruption caused by a buffer under-run phenomenon.

The present invention provides, in a first aspect thereof, a clock signal generator comprising: a first phase comparator for comparing an output clock signal against a first clock signal to output a first phase difference signal; a second phase comparator for comparing the output clock signal against a second clock signal to output a second phase difference signal; a selector for responding to a selection control signal to select one of outputs from the first and second phase comparators to output a selected phase difference signal; a low-pass filter (LPF) for passing the selected phase difference signal to output a voltage signal; and a voltage controlled oscillator (VCO) for responding to the voltage signal to output the output clock signal.

The present invention provides, in a second aspect thereof, a clock signal generator comprising: a first phase comparator for comparing an output clock signal against a first clock signal to output a first phase difference signal; a second phase comparator for comparing the output clock signal against a second clock signal to output a second phase difference signal; a first charge pump for responding to the first phase difference signal to output a first charging/discharging signal, a second charge pump for responding to the second phase difference signal to output a second charging/discharging signal, a selector for responding to a selection control signal to select one of the first and second charging/discharging signals to output a selected charging/discharging signal; a capacitor charged or discharged by the selected charging/discharging signal to output a voltage signal; and a voltage controlled oscillator (VCO) for responding to the voltage signal to output the output clock signal.

In accordance with the clock signal generator of the present invention, the switching of the output clock signal between the frequency of the first clock signal and the frequency of the second clock signal can be conducted during the time interval specified by the time constant of the LPF, whereby continuity of the read clock signal is obtained from the recorded data in an optical disk reader, the recorded data being recorded before and after the interruption caused by the buffer under-run phenomenon in an optical disk recorder having the clock signal generator of the present invention.

### BRIEF DESCRIPTION OF THE DRAWINGS

FIG. 1 is a block diagram of a conventional clock signal generator.

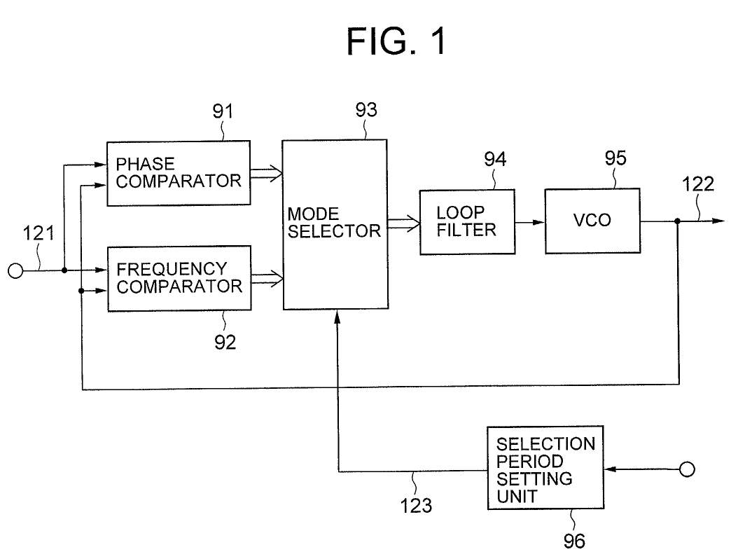

FIG. 2 is a block diagram of an optical disk recorder including a clock signal generator according to a first embodiment of the present invention.

FIG. 3 is a block diagram of the clock signal generator shown in FIG. 2.

FIG. 4 is a timing chart showing frequency of the output clock signal from the clock signal generator of FIG. 3.

FIG. 5 is a circuit diagram of a principal part of a clock signal generator according to a second embodiment of the present invention.

### PREFERRED EMBODIMENTS OF THE INVENTION

Now, the present invention is more specifically described with reference to accompanying drawings, wherein similar constituent elements are designated by similar reference numerals.

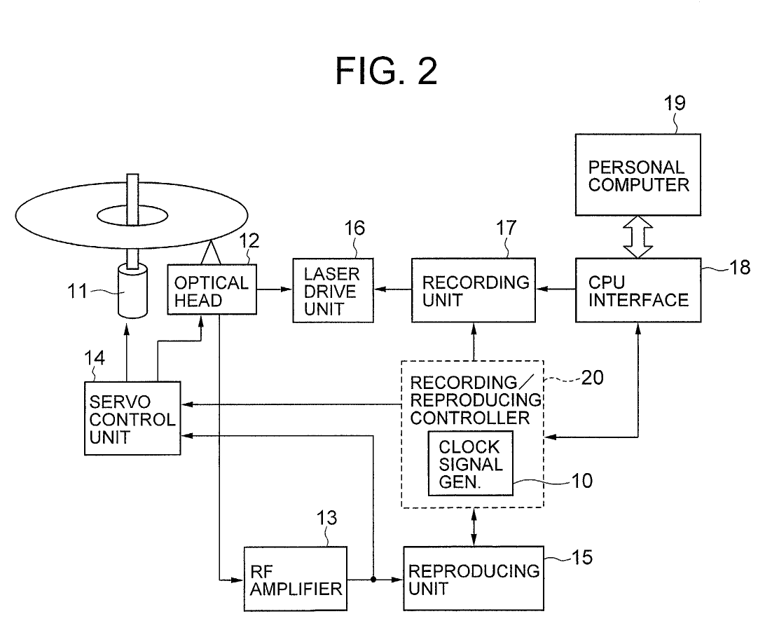

Referring to FIG. 2, there is shown an optical disk recorder including a clock signal generator according to a first embodiment of the present invention. The optical disk recorder includes a spindle motor 11, an optical head 12, a radio-frequency (RF) amplifier 13, a servo control unit 14, a reproducing unit 15, a laser drive unit 16, a recording unit 17, a CPU interface 18, and a recording/reproducing controller 20. A personal computer 19 controls the optical disk recorder to perform recording/reproducing of data on an optical disk, or a CD-R, driven by the spindle motor 11.

The spindle motor 11 controls rotation of the optical disk based on the control signal supplied from the servo control unit 14. Based on the control signal supplied from the servo control unit 14, the optical head 12 controls irradiation by the laser, records desired data on the optical disk or supplies the read data from the optical disk to the RF amplifier 13. The RF amplifier 13 amplifies the read data constituting a RF signal, and delivers the resultant signal to the servo control unit 14 and the reproducing unit 15.

The servo control unit 14 controls, based on read data from the RF amplifier 13 and the control signal from the recording/reproducing controller, rotation of the spindle motor 11, focusing of the laser beam onto the signal track of the optical disk, tracking of the laser beam along the signal track of the optical disk, and sledding of the optical head 12 to move the optical head in the radial direction of the optical disk. The reproducing unit 15 performs EFM (eight to fourteen modulation) demodulation, CIRC (cross interleaved Reed-Solomon Code) decoding processing and error correction, and delivers the read data to the recording/reproducing controller 20.

The CPU interface 18 is connected to a personal computer 19 to transfer/receive data, instruction and response thereto. The recording unit 17 receives write data from the personal computer 19 via the CPU interface 18, operates for CIRC encoding, addition of a sub-code, addition of error correcting codes, EFM modulation, etc. onto the received write data, and supplies the resultant write data to the laser drive unit 16. The laser drive unit 16 performs drive control of the laser source in the optical head 12 based on the write data supplied from the recording unit 17.

The recording/reproducing controller 20 includes the clock signal generator 10 of the present embodiment. The recording/reproducing controller 20 controls recording processing and reproduction processing based on the instruction from the personal computer 19 and the read data from the reproducing unit 15. The clock signal generator 10 generates a reproducing clock signal for use in reproduction of recorded data, and a recording clock signal used for use in recording of write data onto the optical disk.

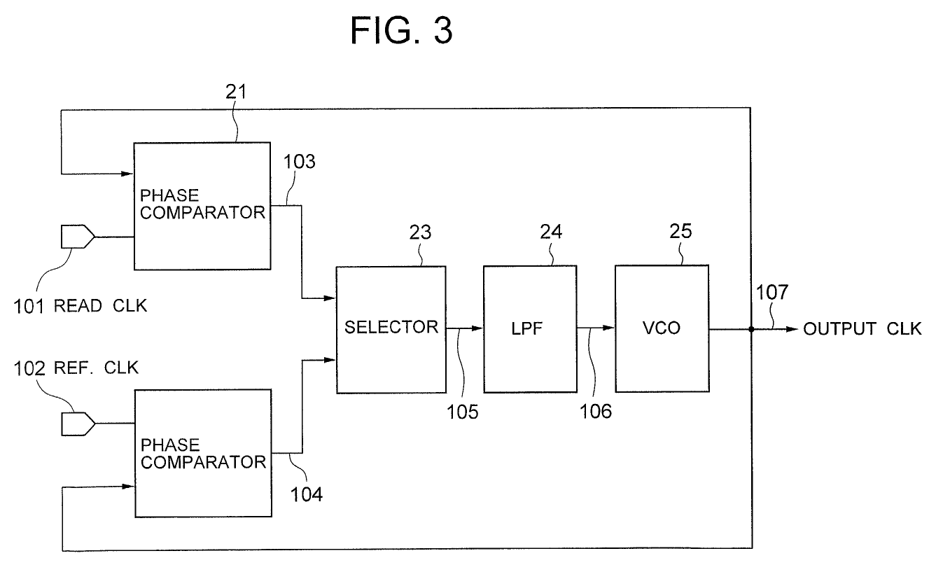

Referring to FIG. 3, the clock signal generator 10 includes first and second phase comparators 21 and 22, a selector 23, a low-pass-filter (LPF) 24, and a voltage controlled oscillator (VCO) 25. The first phase comparator 21 compares the phase of the read data pulse or (read clock signal) 101 against the phase of the output clock signal 107 to generates a first difference signal representing the difference between the phases of both the clock signals 101 and 107, and delivers the first difference signal 103 to the selector 23.

The second phase comparator 22 compares the phase of the reference clock signal 102 against the phase of the output clock signal 107, to generate a second difference signal 104 representing the difference between the phases of both the clock signals 102 and 107, and delivers the second difference signal 104 to the selector 23.

The selector 23 selects the first difference signal 103 during a reproducing operation, selects the second phase difference signal 104 during a recording operation, and delivers the selected difference signal to the LPF 24. The LPF 24 smoothes the selected difference signal to output a voltage signal 106 to the VCO 25. The voltage signal 106 has a potential which changes at a fixed time constant Tx defined by the LPF 24. The VCO 25 oscillates based on the voltage signal 106 to generate the output clock signal 107.

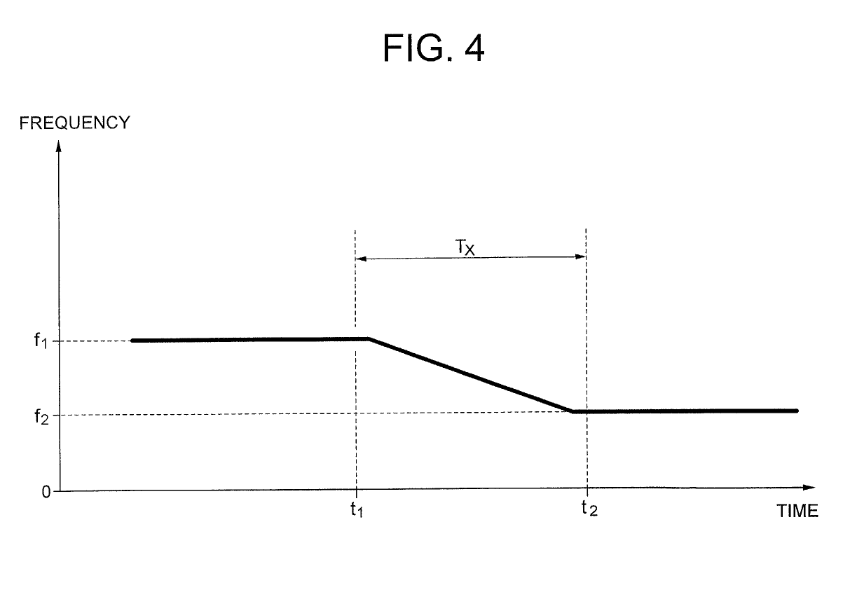

Referring to FIG. 4, the frequency of the output clock signal 107 falls from f1 to f2 from a reproducing operation to a recording operation in the optical disk recorder. More specifically, the selector 23 selects the first difference signal 103 before time instant t1, whereby the voltage signal 106 is maintained at a first potential based on the first difference signal 103. The VCO 25 oscillates based on the voltage signal 106 to deliver the output clock signal 107 having a stable frequency f1.

At time instant t1, the selector 23 selects the second difference signal 104, whereby the selected difference signal 105 abruptly changes the waveform thereof with respect to the pulse width and the period thereof.

Between the time instants t1 and t2, the selector 23 selects the second difference signal 104, whereby the voltage signal 106 linearly falls from the first potential to a second potential. The frequency of the output clock signal 107 from the VCO 25 linearly falls from the frequency f1 to a frequency f2 in proportion to the voltage signal 106.

After the time instant t2, the selector continues to select the second difference signal 104, whereby the voltage signal 106 is maintained at the second potential based on the selected difference signal. Thus, the VCO 25 oscillates to output a clock signal 107 having a stable frequency f2.

The time interval between t1 and t2 is determined by the time constant Tx of the LPF 24. The time constant Tx of the LPF 24 is set a desired value for assuring the specified range of deviation allowed for recording data on the CD-R after the interruption caused by the buffer under-run phenomenon.

The read clock signal 101 is obtained by reading the data recorded on the CD-R prior to the interruption. The reference clock signal 102 is obtained by multiplying an output frequency from a crystal oscillator, if the rotation of the spindle motor 11 is to be controlled at a constant linear velocity of the CD-R. On the other hand, if the spindle motor is to be controlled at a constant angular velocity of the CD-R, the reference clock 102 signal is obtained by extracting wobble signal component having a frequency of 22.05 kHz from a pre-groove signal which is output from the RF amplifier 13, and generating a clock signal in synchrony with the wobble signal component.

The frequency f2 of the reference clock signal 102 may be higher than the frequency f1 in the clock signal generator 10.

Now operation of the optical disk recorder for additionally recording data on a CD-R after an interruption is described. It is assumed that data is recorded on the CD-R up to the end point before interruption of recording due to the buffer under-run phenomenon. When the optical disk recorder receives an instruction for recording from the personal computer 19, the recording/reproducing controller 20 starts for processing of additional recording.

The servo control unit 14 operates for focusing control and tracking control of the optical head 12, and for rotational control of the spindle motor 11. The recording unit 17 receives write data from the personal computer 19 and operates for processing of the received write data.

The optical disk recorder judges whether the focusing, tracking and rotational controls operate in normal conditions and whether the recording unit 17 is ready for recording, before the optical disk starts for reading the recorded data to detect the starting position for recording. The selector 23 selects the first difference signal 103, whereby the VCO 25 generates a reproducing clock signal in synchrony with the read clock signal 101. The optical disk recorder reproduces the data recorded on the optical disk before the interruption based on the reproducing clock signal, thereby detecting the end point of the recorded data as the starting position for the recording.

Upon detection of the starting point, the selector 23 selects the second difference signal 104, whereby the VCO 25 generates a recording clock signal in synchrony with the reference clock signal 102. The recording unit 17 starts for recording operation based on the recording clock signal. The optical disk recorder thus records the write data on the optical disk via the laser drive unit 16 and the recording unit 17 from the starting point.

During switching from the reproducing operation to the recording operation, the selected phase difference signal 105 from the selector 23 changes abruptly in the pulse waveform thereof. However, the time constant Tx of the LPF 24 suppresses the abrupt change in the potential of the voltage signal 106, which changes linearly. Thus, the output frequency from the VCO 25 changes linearly, as illustrated in FIG. 4, before the output clock signal synchronizes with the reference clock signal 102.

In reproduction of the data recorded by the above optical disk recorder, the optical disk reader receives a read clock signal having an excellent continuity between the vicinity of the end point and the vicinity of the starting point.

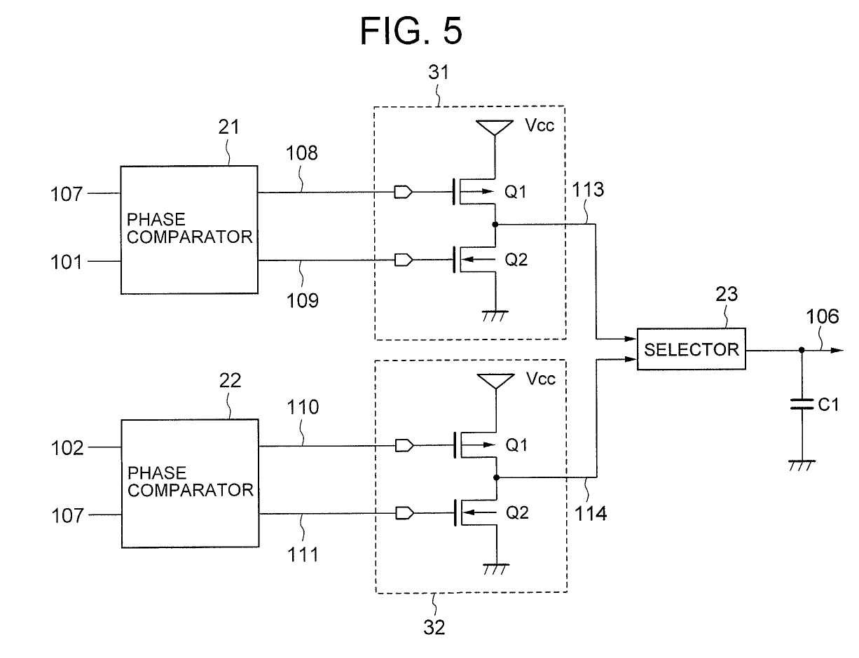

Referring to FIG. 5, a clock signal generator according to a second embodiment of the present invention is similar to clock signal generator of the first embodiment, except that a pair of charge pumps 31 and 32 are provided in the present embodiment between the phase comparators 21 and 22 and the selector 23 instead of the LPF 24 shown in FIG. 3, and each phase comparator 21 or 22 generates a pair of phase difference signals 108 and 109 or 110 and 111.

More specifically, each charge pump 31 or 32 includes a p-ch transistor Q1 and an n-ch transistor Q2 connected in series between the VCC source line and the ground. The transistor Q1 charges the output line 113 or 114, i.e., capacitor C1, through the selector 23, whereas the transistor Q2 discharges the output line 113 or 114, i.e., capacitor C1, through the selector 23. The relationship between the phase difference signals 108 and 109 or 110 and 111 from each phase comparator 31 or 32 and the rise/fall of the output signal line 113 or 114 of the each charge pump 31 or 32 is shown in Table 1.

TABLE 1

| 108, 110(Q1) | L | H | H | L |
|---|---|---|---|---|
| 109, 111(Q2) | L | H | L | H |
| 113, 114 | Rise | Fall | Hold | Prohibited |

Each phase comparator 21 or 22 judges whether the output clock signal 107 advances or lags with respect to the read clock signal 101 or reference clock signal 102, and delivers a pair of phase difference signals 108 and 109 or 110 and 111 having H- or L-levels depending on the results of the comparison.

The first charge pump 31 connected to the first phase comparator 21 has a higher current driveability compared to the second charge pump 32 connected to the second phase comparator 22. By this configuration of the clock signal generator, the reproducing clock signal locks with the read clock signal 101 at a higher rate compared to the locking rate of the recording clock signal with respect to the reference clock signal 102. This allows a higher shift rate in the shift of the optical disk recorder from a recording operation to a reproducing operation compared to the shift from a read operation to a recording operation, whereby continuity of the recorded data is further improved.

According to the present embodiment, the charge pumps provided instead of the LPF suppress the ripple components on the voltage signal supplied to the VCO, thereby widening the frequency range of the input clock signal to the clock signal generator which can be compared against the output clock signal from the clock signal generator.

Since the above embodiments are described only for examples, the present invention is not limited to the above embodiments and various modifications or alterations can be easily made therefrom by those skilled in the art without departing from the scope of the present invention.

What is claimed is:

1. A clock signal generator comprising:
a first phase comparator for comparing an output clock signal against a first clock signal to output a first phase difference signal;
a second phase comparator for comparing said output clock signal against a second clock signal to output a second phase difference signal;
a selector for responding to a selection control signal to select one of outputs from said first and second phase comparators to output a selected phase difference signal;
a low-pass filter (LPF) for passing said selected phase difference signal to output a voltage signal; and
a voltage controlled oscillator (VCO) for responding to said voltage signal to output said output clock signal.

2. The clock signal generator as defined in claim 1, wherein said output clock signal is used for recording and reproducing data on a CD-R, said first clock signal is a read clock signal read from said CD-R, and said second clock signal is a reference frequency signal having a recording frequency for recording data on said CD-R.

3. The clock signal generator as defined in claim 2, wherein said output clock signal is switched between a frequency of said first clock signal and a frequency of said second clock signal during a time interval specified by a time constant of said LPF.

4. A clock signal generator comprising:
a first phase comparator for comparing an output clock signal against a first clock signal to output a first phase difference signal;
a second phase comparator for comparing said output clock signal against a second clock signal to output a second phase difference signal;
a first charge pump for responding to said first phase difference signal to output a first charging/discharging signal,
a second charge pump for responding to said second phase difference signal to output a second charging/discharging signal,
a selector for responding to a selection control signal to select one of said first and second charging/discharging signals to output a selected charging/discharging signal;
a capacitor charged or discharged by said selected charging/discharging signal to output a voltage signal; and
a voltage controlled oscillator (VCO) for responding to said voltage signal to output said output clock signal.

5. The clock signal generator as defined in claim 4, wherein said output clock signal is used for recording and reproducing data on a CD-R, said first clock signal is a read clock signal read from said CD-R, and said second clock signal is a reference frequency signal having a recording frequency for recording data on said CD-R.

6. The clock signal generator as defined in claim 4, wherein said first charge pump has a current driveability higher than a current driveability of said second charge pump.
